(19) United States
(12) Patent Application Publication
(10) Pub. No.: US 2024/0186346 A1
(43) Pub. Date: Jun. 6, 2024

(54) SEMICONDUCTOR PACKAGING FOR IMAGE SENSORS

(71) Applicant: UTAC Headquarters Pte. Ltd., Singapore (SG)

(72) Inventors: Jeffrey Punzalan, Singapore (SG); Catherine Cheh Yee Chang, Singapore (SG); Il Kwon Shim, Singapore (SG)

(21) Appl. No.: 18/516,997

(22) Filed: Nov. 22, 2023

Related U.S. Application Data
(60) Provisional application No. 63/429,159, filed on Dec. 1, 2022.

(51) Int. Cl. H01L 27/146; H01L 23/00

(52) U.S. Cl. CPC H01L 27/14618; H01L 24/45; H01L 24/48; H01L 27/14683; H01L 24/32; H01L 27/14636; H01L 2224/32225; H01L 2224/45144; H01L 2224/48091; H01L 2224/48108; H01L 2224/48227

(57) ABSTRACT

A semiconductor package for a sensor is disclosed. The package includes an opaque layer on the encapsulation to prevent the wire bonds encased by the encapsulation from being visible to the naked eye. This reduces or prevents reflectance which improves the performance of the sensor. In some cases, the opaque layer extends beyond the encapsulation to cover a peripheral portion of the cover to form a cover opaque region. The cover opaque region reduces or prevents flaring and scattering of light, further enhancing the performance of the sensor.

### CROSS-REFERENCE TO RELATED APPLICATION

This application claims the benefit of U.S. Provisional Application No. 63/429,159, filed on Dec. 1, 2022, which is incorporated herein by reference in its entirety for all purposes.

### FIELD OF THE INVENTION

The present disclosure relates to semiconductor packages for image sensors and manufacturing methods of such packages. In particular, the present disclosure relates to semiconductor packages with an opaque coating to obscure wire bonds which can cause reflectance, negatively affecting the performance of the image sensors.

### BACKGROUND

Semiconductor packages are employed for packaging semiconductor chips. For example, in the case of sensor packages, they are employed for packaging sensor chips. A sensor chip includes a sensor for sensing non-electrical signals from the surrounding environment. The sensor chip converts the non-electrical signals received into electrical signals that are transmitted to a printed circuit board. For example, an image sensor chip converts incoming light into an electrical signal that can be viewed, analyzed, or stored. Image sensors may be used in electronic imaging devices of both analog and digital types, which include digital cameras, camera modules and medical imaging equipment. Commonly used image sensors may include semiconductor charge-coupled devices (CCD) or active pixel sensors formed using complementary metal-oxide-semiconductor (CMOS) or N-type metal-oxide-semiconductor (NMOS, Live MOS) technologies.

Typically, a sensor package includes wire bonds. Although the wire bonds are encased in an encapsulation, they can still be visible to the naked eye and can cause reflectance. This may impact the performance of the sensor chip and cause yield loss.

From the foregoing discussion, there is a desire to provide semiconductor packages with covers that can prevent the reflectance of visible wire bonds, thereby improving the performance of semiconductor sensor packages.

### SUMMARY

Embodiments generally relate to semiconductor packages and methods for manufacturing thereof.

In one embodiment, the present disclosure is related to a semiconductor package. The semiconductor package includes a package substrate with top and bottom major package substrate surfaces. The top package substrate surface includes a die region with a die pad and a non-die region. The non-die region includes package bond pads and a cover adhesive surrounding the die region. The bottom package substrate surface includes package contact pads. The package contact pads on the bottom package substrate surface are electronically connected to respective package bond pads on the top package substrate surface. The semiconductor package also includes a sensor die having active and non-active major die surfaces. The active die surface includes a sensor region with a sensor, a non-sensor region with die bond pads and a cover adhesive region surrounding the sensor region. The non-active die surface is attached to the die pad. The semiconductor package also includes wire bonds connecting the die bond pads on the active die surface and package bond pads on the top package substrate surface. The semiconductor package also includes a transparent cover disposed over the die covering the sensor region. The cover is attached by a cover adhesive on the cover adhesive region of the active die surface. The cover forms a sealed cavity between the cover and sensor. The semiconductor package also includes a package encapsulation. The package encapsulation encapsulates the package substrate, wire bonds and side cover surfaces and outer sides of the cover adhesive. The semiconductor package further includes an opaque layer disposed on a top surface of the package encapsulation. The opaque layer obscures the wire bonds within the encapsulation to reduce reflectance to improve sensor performance.

In another embodiment, a method for forming a semiconductor package is disclosed. The method includes providing a package substrate with top and bottom major package substrate surfaces. The top package substrate surface includes a die region with a die pad and a non-die region. The non-die region includes package bond pads and a cover adhesive region surrounding the die region. The bottom package substrate surface includes package contact pads. The package contact pads on the bottom package substrate surface are electrically connected to respective package bond pads on the top package substrate surface. The method also includes providing a sensor die having active and non-active major die surfaces. The active die surface includes a sensor region with a sensor, a non-sensor region with die bond pads and a cover adhesive region surrounding the sensor region. The method also includes attaching the inactive die surface of the die to the die pad. The method also includes performing wire bonding to electrically connect the die bond pads on the active die surface and package bond pads on the top package substrate surface. The method also includes attaching a transparent cover over the die covering the sensor region by a cover adhesive on the cover adhesive region of the top package substrate surface. The cover forms a sealed cavity between the cover and sensor. The method also includes encapsulating the package with a package encapsulation. The package encapsulation encapsulates the package substrate, wire bonds and side cover surfaces and outer sides of the cover adhesive. The method further includes forming an opaque layer on a top surface of the package encapsulation. The opaque layer obscures the wire bonds within the encapsulation to reduce reflectance to improve sensor performance.

In yet another embodiment, the present disclosure is related to a semiconductor package. The semiconductor package includes a package substrate with top and bottom major package substrate surfaces. The top package substrate surface includes a die region with a die pad and a non-die region, the non-die region includes package bond pads and a cover adhesive region surrounding the die region. The bottom package substrate surface includes package contact pads. The package contact pads on the bottom package substrate surface are electrically connected to respective package bond pads on the top package substrate surface. The semiconductor package also includes a sensor die having active and non-active major die surfaces. The active die surface includes a sensor region with a sensor, a non-sensor region with die bond pads and a cover adhesive region surrounding the sensor region. The inactive die surface is attached to the die pad. The semiconductor package also includes wire bonds connecting the die bond pads on the active die surface and package bond pads on the top package substrate surface. The semiconductor package also includes a transparent cover disposed over the die covering the sensor region. The cover is attached by a cover adhesive on the cover adhesive region of the top package substrate surface. The cover forms a sealed cavity between the cover and sensor. The semiconductor package also includes a package encapsulation. The package encapsulation encapsulates the package substrate, wire bonds and side cover surfaces and outer sides of the cover adhesive. The semiconductor package further includes an opaque layer disposed on a top surface of the package encapsulation. The opaque layer obscures the wire bonds within the encapsulation to reduce reflectance to improve sensor performance.

These and other advantages and features of the embodiments herein disclosed will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of various embodiments. In the following description, various embodiments of the present disclosure are described with reference to the following, in which:

FIGS. 1a-1b show simplified top and cross-sectional views of an embodiment of a semiconductor package:

FIGS. 2a-2b show simplified top and cross-sectional views of another embodiment of a semiconductor package:

FIGS. 3a-3f show simplified cross-sectional views of an embodiment of a process for forming a semiconductor package:

FIGS. 4a-4c show simplified top views of a process for forming multiple packages in parallel: and

FIG. 4d shows a simplified top view of another embodiment of coating multiple packages in parallel.

### DETAILED DESCRIPTION

Embodiments described herein generally relate to semiconductor packages and methods for forming thereof. In some embodiments, the semiconductor package includes a sensor chip used for sensing environmental signals. In particular, the semiconductor package includes an image sensor chip. The semiconductor package includes a cover over the sensor chip and encapsulant. The cover protects the active sensor chip surface with the sensor(s). The cover, for example, is a transparent cover, such as a glass cover. The encapsulant is covered by an opaque layer. This prevents the wire bonds of the package from being visible to avoid reflectance. Reflectance can impact the performance of the sensor chip as well as cause yield loss. In some applications, the cover includes an opaque region surrounding a periphery thereof. The opaque region prevents flaring or scattering of light to further improve package performance. The semiconductor package may be incorporated into electronic devices or equipment, such as sensing devices, navigation devices, telecommunication devices, computers and smart devices.

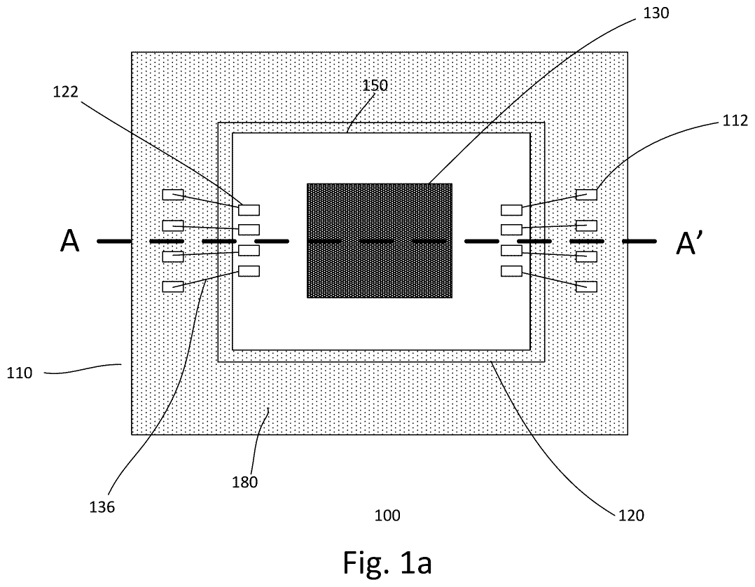

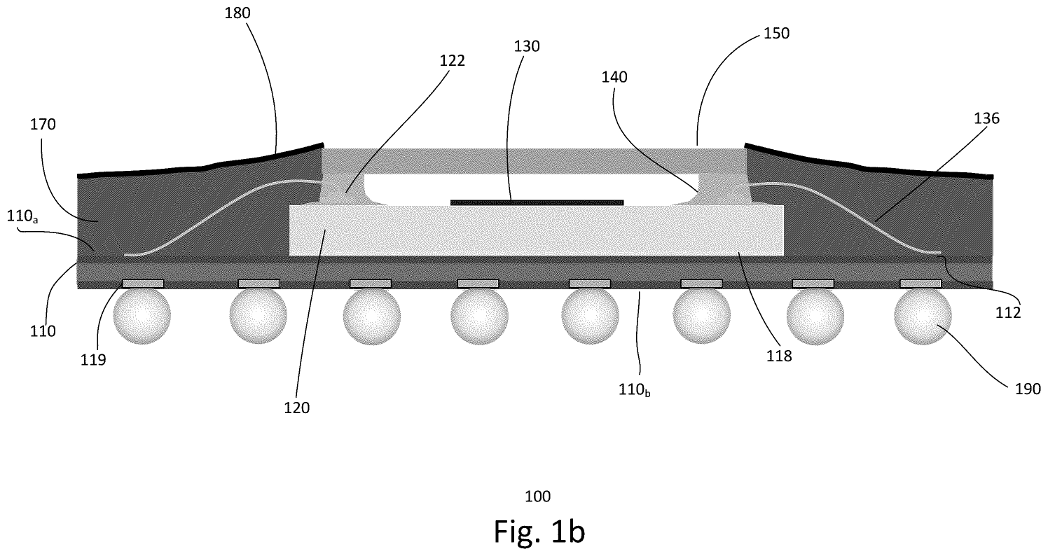

FIGS. 1a-1b show a simplified top view and a simplified cross-sectional view along A-A′ of an embodiment of a semiconductor package. Referring to FIGS. 1a-1b, a semiconductor package 100 is shown. The semiconductor package 100 includes a package substrate 110 having opposing first and second major surfaces 110a and 110b. The first major surface 110a may be referred to as the top substrate surface and the second major surface 110b may be referred to as the bottom substrate surface. The top surface serves as a bonding surface for a die 120. For example, the top surface includes a die pad region on which a die is attached.

The die pad may be referred to as a die region of the top package substrate surface while the non-die pad region may be referred to as a non-die region. The non-die region, for example, surrounds the die region. The die region may be centrally disposed within the top surface of the package substrate with the non-die region surrounding it. Other configurations of the die and non-die regions may also be useful. For example, the die region may not be centrally disposed within the top package surface.

The package substrate may be a multi-layered substrate. For example, the package substrate includes a stack of electrically insulating substrate layers with interconnect lines therebetween. The different layers of the package substrate 110 may be laminated or built up. Via contacts are provided in the insulating layers to interconnect interconnect lines of other layers. In one embodiment, the package substrate is a laminate-based substrate including a core or intermediate layer sandwiched between top and bottom substrate layers. Other types of substrates, including ceramic and leadframe substrates, may also be useful. It is understood that the package substrate may have various configurations, depending on design requirements.

The top surface of the package substrate may include package bond pads 112. The package bond pads are disposed in the non-die region of the top package substrate surface. The bottom package surface may include package pads 119 with package contacts 190 connected thereto. The package pads, for example, are electrically coupled to the package bond pads of the top surface of the package substrate. For example, each package pad is coupled to its respective package bond pad. The package substrate may include one or more conductive layers embedded therein. The conductive layers may form interconnect structures including conductive traces and via contacts for interconnecting the package contacts to package bond pads. The package contacts provide external connections to the package.

A die 120 is attached to the die pad on the top package substrate surface. The die, for example, includes first and second opposing major die surfaces. The first major surface may be referred to as a top or active die surface and the second major surface may be referred to as a bottom or inactive die surface. In one embodiment, the die is a sensor chip. For example, the active or top die surface includes a sensor region with a sensor 130. The sensor region may be centrally disposed on the top die surface surrounded by a non-sensor region. Other configurations of the sensor and non-sensor regions may also be useful.

In one embodiment, the die is an image sensor chip. The image sensor chip, for example, includes an image sensor for detecting radiation or light. The image sensor, for example, a CMOS or CCD type image sensor. Other types of sensors may also be useful. In one embodiment, the sensor region includes an array of sensors. For example, each sensor may correspond to a pixel of an image. The sensor chip may include CMOS components embedded in the chip for controlling the sensor chip. Other configurations of the sensor chip may also be useful.

The die, as shown, is attached to the die region of the package substrate by a die adhesive 118. The adhesive may be a curable glue or adhesive tape. For example, a curing process may be performed to permanently attach the die to the die region. Other types of die adhesives may also be useful to attach the die to the die region. The bottom surface of the die, for example, is attached to the die region. For example, the inactive die surface is attached to the die region of the package substrate. The adhesive may be cured to permanently attach the die to the package substrate.

The active die surface may include die bond pads 122 disposed outside of the sensor region. For example, the die bond pads may be disposed on the non-sensor region of the active surface of the die. The die bond pads provide external electrical connections to various components of the chip. In one embodiment, wire bonds 136 are provided to couple the package bond pads to the die bond pads. The wire bonds, for example, are gold wire bonds. Other conductive wire bonds may also be useful. The wire bonds enable external connections to the internal circuitry of the die.

A cover 150 is disposed on the die over the sensor region. The cover includes first or top and second or bottom opposing major cover surfaces and side surfaces. In one embodiment, the cover is a rectangular-shaped cover with opposing top and bottom surfaces and four side surfaces. Other shaped covers may also be useful. The bottom cover surface, for example, faces the die. The cover is a transparent cover to enable light or radiation to penetrate through to the sensor region. For example, the cover may be a glass cover. Other types of transparent cover may also be useful. The cover thickness of the cover may be about 0.4-0.5 mm. Other thicknesses may also be useful.

A cover adhesive 140 may be employed to attach the cover 150 over the die. In one embodiment, the top die surface includes an adhesive region on which the cover adhesive is disposed. The adhesive region, for example, surrounds the sensor region. In one embodiment, as shown, the adhesive region is disposed on a periphery portion of the die active surface with a gap or space between the outer edge of the sensor region and the inner sides of the adhesive region. For example, an adhesive ring 140 is disposed on the adhesive region surrounding the sensor region for attaching the cover 150 to the die. The adhesive may be a curable adhesive. For example, a curing process may be performed to permanently attach the cover to the die. In one embodiment, the curing process to attach the cover is separate from the curing process to attach the die. In one embodiment, the die pads are disposed within the adhesive region. This reduces the footprint of the die, and as a result, the package. Providing the die pads outside of the adhesive region may also be useful.

The cover sufficiently covers the sensor region. For example, the center portion of the bottom cover surface has a rectangular shape which is larger than the sensor region, ensuring that it sufficiently covers the sensor region. Providing a center portion of the bottom cover surface with other shapes may also be useful. The cover forms a vacuum cavity over the sensor region. For example, the cover hermetically seals the sensor region.

In one embodiment, the bottom surface of the cover includes a bonding region. The bonding region, for example, may be referred to as a cover bonding region. The bonding region is aligned with the adhesive region on the active surface of the die. For example, the bonding region is a continuous ring-shaped region which is aligned with the cover adhesive region. The adhesive bonds the cover to the active surface of the die.

An encapsulant or encapsulation 170 is disposed on the package substrate. The encapsulant 170 covers the package substrate, exposed portions of the die, wire bonds and sides of the cover 150. The encapsulant leaves the top of the cover exposed. The top of the encapsulant, as shown is sloped. Other configurations of the top encapsulant surface may also be useful. For example, the top encapsulant surface may be a planar surface. The encapsulant may be a mold compound, such as an epoxy mold compound (EMC). Other types of encapsulants may also be useful. The encapsulant may be formed by dispensing filler epoxy. Alternatively, injection molding may be employed. For example, transparent EMC may be employed to encapsulate the device by molding followed by forming the opaque layer over the planar encapsulant surface.

In one embodiment, a top surface of the encapsulant is covered with an opaque layer 180. The opaque layer prevents the wire bonds under the encapsulant from being visible to the naked eye. By making the wire bonds invisible, reflectance from the wire bonds is avoided. This improves the performance of the optical package. In one embodiment, the opaque layer is a black ink layer. The thickness of the opaque layer may be about 700 to 725 um. Other types of opaque layers or thicknesses may also be useful. The opaque layer may be selectively formed on the encapsulant top surface by inkjet printing. Other techniques may also be employed to form the opaque layer on the encapsulant top surface. For example, pad stamping or squeegee using a mask with openings corresponding to location of the opaque layer may be employed.

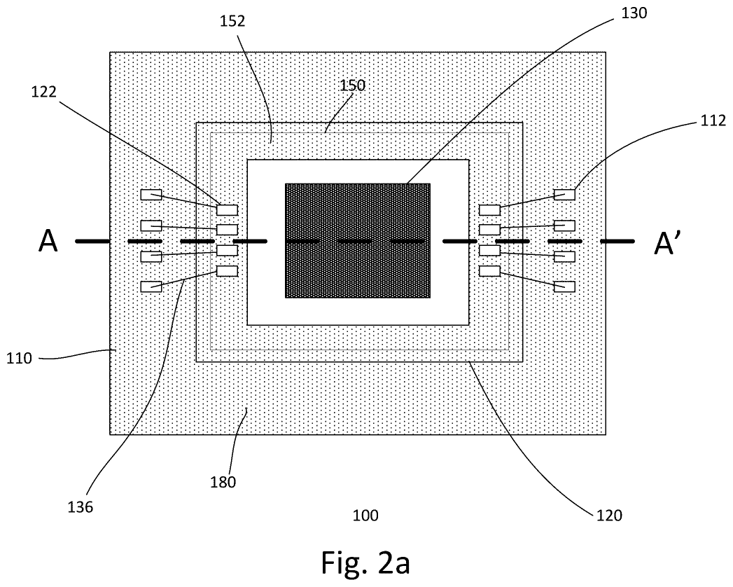

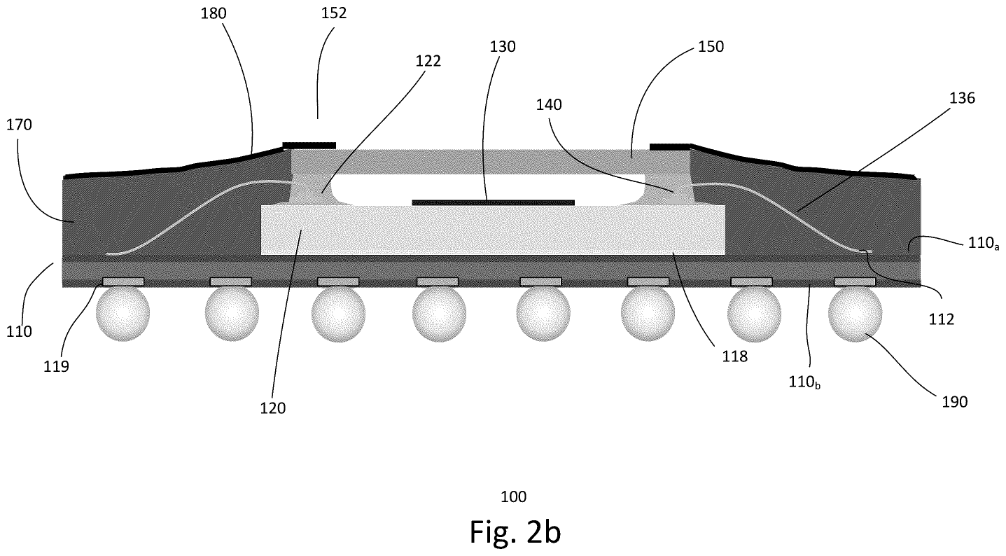

FIGS. 2a-2b show a simplified top view and a simplified cross-sectional view along A-A′ of an embodiment of a semiconductor package. The package is similar to the package of FIGS. 1a-1b. Common elements may not be described or described in detail.

Referring to FIGS. 2a-2b, a semiconductor package 100 is shown. The semiconductor package 100 includes a package substrate 110 on which a sensor die 120 is attached using a die adhesive 118. Wire bonds 136 connect the die pads 122 to package pads 112. A transparent cover 150 is attached to the top die surface by a cover adhesive 140. An encapsulant 170 encapsulates the package. The encapsulant encapsulates, the package substrate, exposed portions of the die, wire bonds, and sides of the cover while leaving the top cover surface exposed.

In one embodiment, a top surface of the encapsulant is covered with an opaque layer 180. This prevents the wire bonds from being visible. In addition, the opaque layer covers a peripheral region of the top cover surface, forming an opaque cover region 152. The opaque cover region prevents flaring or scattering of light to the sensor. In one embodiment, the width of the opaque region on the cover may be about 150-200 um. Providing other widths for the opaque region may also be useful. By covering the encapsulant and opaque cover region with the opaque layer, sensor performance and yields are improved. For example, the light passing through the cover has minimal reflectance from the encapsulant. The light concentration in the cavity is increased, thus improving the sensor optical performance. Accordingly, the performance and reliability of the package is improved.

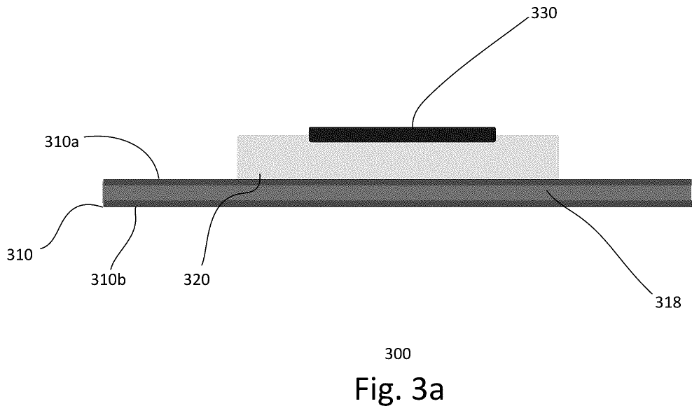

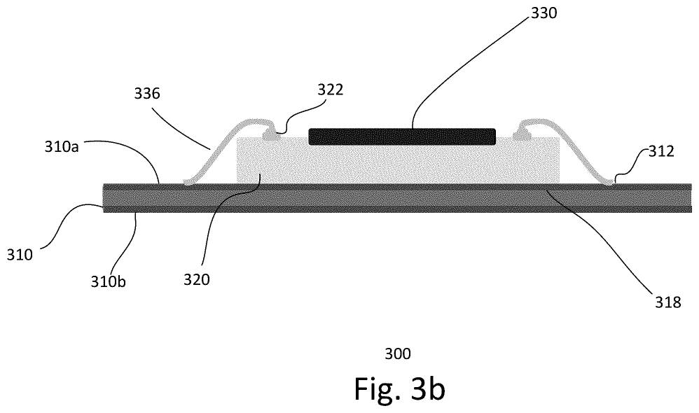

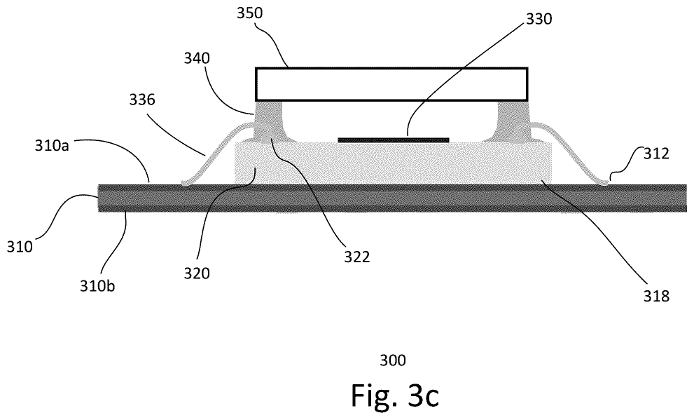

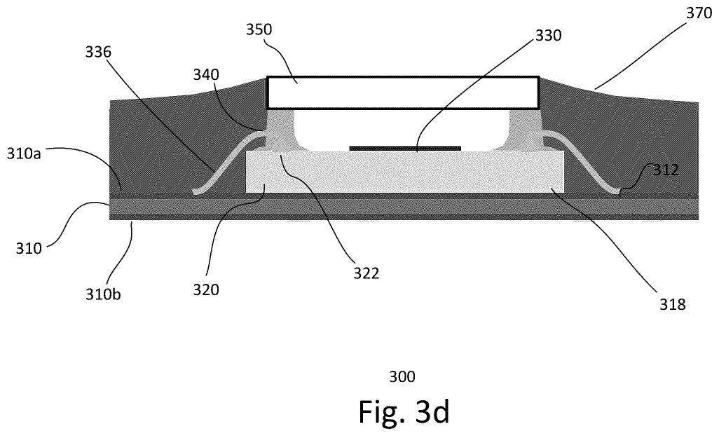

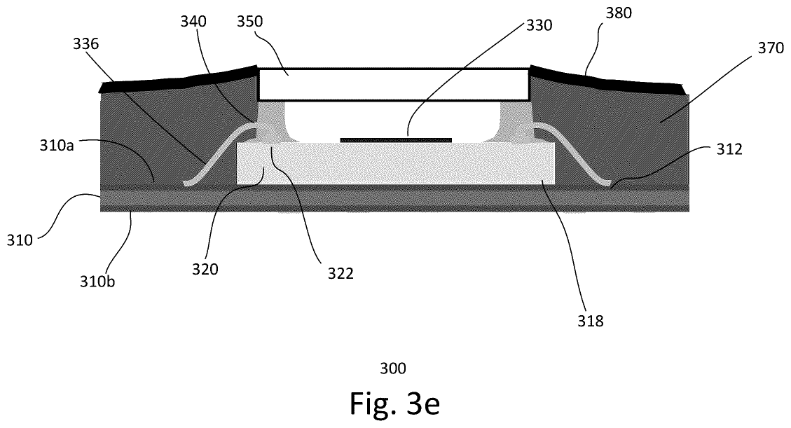

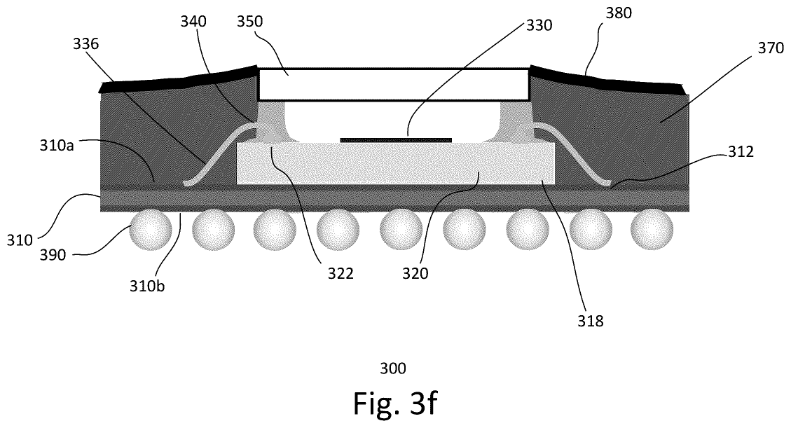

FIGS. 3a-3f show simplified cross-sectional views of an embodiment of a process flow 300 for forming a semiconductor package. The semiconductor package is similar to those described in FIGS. 1a-1b and 2a-2b. Common elements may not be described or described in detail.

Referring to FIG. 3a, a package substrate 310 having opposing first (top) and second (bottom) major surfaces 310a and 310b is provided. The package substrate may be a multi-layered substrate. The different layers of the package substrate may be laminated or built up. In one embodiment, the package substrate is a laminate-based substrate including a core or intermediate layer sandwiched between top and bottom substrate layers. Other types of substrates, including ceramic and leadframe substrates, may also be useful. It is understood that the package substrate may have various configurations, depending on design requirements.

The top package substrate surface includes a die pad for attaching a die thereto. The die pad forms a die region of the top package substrate surface while a non-die region corresponds to the substrate surface outside of the die region. The non-die region may be configured to surround the die region. Other configurations of the die and non-die regions may also be useful.

The top package substrate surface also includes package bond pads. The package bond pads, in one embodiment, are disposed in the non-die region. As for the bottom package substrate surface, it may include package pads (not shown). The package pads on the bottom package substrate surface, for example, are electrically coupled to the package bond pads on the top surface of the package substrate. For example, each package pad is coupled to its respective package bond pad. The package substrate may include one or more conductive layers embedded therein. The conductive layers may form interconnect structures including conductive traces and via contacts for interconnecting the package pads on the bottom package surface to the package bond pads on the top package surface.

A die or chip 320 is aligned and attached to the die pad on the top package substrate surface. The die includes first (active) and second (inactive) major die surfaces. The inactive surface is attached to the package substrate by a die adhesive 318. The die adhesive may be a curable glue or adhesive tape. For example, a curing process may be performed after attaching the die to the die pad, permanently attaching it thereto. Other types of die adhesives may also be useful to attach the die to the die pad.

In one embodiment, the die is a sensor chip. For example, the active die surface includes a sensor region with a sensor 330. The sensor region may be centrally disposed on the top die surface surrounded by a non-sensor region. Other configurations of the sensor and non-sensor regions may also be useful.

In one embodiment, the die is an image sensor chip. The image sensor chip, for example, includes an image sensor for detecting radiation or light. The image sensor, for example, a CMOS or CCD type image sensor. Other types of sensors may also be useful. In one embodiment, the sensor region includes an array of sensors. For example, each sensor may correspond to a pixel of an image. The sensor chip may include CMOS components embedded in the chip for controlling the sensor chip. Other configurations of the sensor chip may also be useful.

The active die surface may include die bond pads disposed outside of the sensor region. For example, the die bond pads may be disposed on the non-sensor region of the active surface of the die.

In FIG. 3b, wire bonds 336 are formed. In one embodiment, wire bonds are formed by a wire bonding process, electrically connecting die bond pads 322 on the active die surface outside of the sensor region to package bond pads 312 on the non-die region of the top package substrate surface.

As shown in FIG. 3c, the sealing process for sealing the sensor region of the die is performed. In one embodiment, the sealing process includes dispensing a cover adhesive 340 on a cover adhesive region on the active die surface surrounding the sensor region. For example, an adhesive dispenser is configured to dispense the cover adhesive on the cover adhesive region on the active die surface. For example, the cover adhesive region on the non-sensor region of the active die surface surrounds the sensor region.

The cover adhesive has sufficient viscosity to enable it to form a continuous adhesive ring on the cover adhesive region having a desired height. The desired height may be about 100 to 150 um. Other heights may also be useful, depending on the requirements. The desired height should be able to accommodate the looped wire bonds without damaging them.

In one embodiment, as shown, the die bond pads are disposed within the cover adhesive region. Providing die bond pads inside the cover adhesive region or outside the cover adhesive region may also be useful.

A cover 350 is aligned to the package and attached to the cover adhesive. This forms a cavity over the die, sealing the sensor region. The cover is a transparent cover to enable light or radiation to penetrate through to the sensor region. For example, the cover may be a glass cover. Other types of transparent cover may also be useful. The cover thickness of the cover may be about 0.4-0.5 mm. Other thicknesses may also be useful.

After attaching the cover to the package, a curing process may be performed to permanently attach the cover to the die. The cover structure forms a vacuum cavity over the sensor region. For example, the cover structure hermetically seals the sensor region. In some embodiments, the cavity may be a near hermetic or airtight cavity or a partial vacuum cavity.

Referring to FIG. 3d, an encapsulant 370 is formed to encapsulate the die on the package substrate with the cover attached thereto. The encapsulant may be a mold compound, such as an epoxy mold compound (EMC). Other types of encapsulants may also be useful. The encapsulant may be formed by dispensing filler epoxy. Alternatively, injection molding may be employed. For example, transparent EMC may be employed to encapsulate the device by molding followed by forming the opaque layer over the planar encapsulant surface. The encapsulant covers the package substrate, exposed portions of the die, wire bonds and sides of the cover. The encapsulant leaves the top of the cover exposed. The top of the encapsulant, as shown is sloped. Other configurations of the top encapsulant surface may also be useful. For example, the top encapsulant surface may be a planar surface.

In FIG. 3e, the process forms an opaque layer 380 on the top surface of the encapsulant. As shown, the opaque layer leaves the surface of the cover exposed. The opaque layer, in one embodiment, is a black ink layer. The opaque layer is formed on the top surface of the encapsulant by inkjet printing. Other types of opaque layers or deposition techniques may also be useful. The thickness of the opaque layer should be sufficient to prevent the wire bonds encapsulated by the encapsulant from being visible. For example, the thickness of the black ink layer may be about 700 to 725 um. Other thicknesses may also be useful.

As shown, the opaque layer is formed only on the surface of the encapsulant. In alternative embodiments, the opaque layer may extend beyond the encapsulant and cover the periphery of the top surface of the cover, as shown in FIGS. 2a-2b. For example, the cover includes an opaque region in the periphery thereof.

Referring to FIG. 3f, the process continues to form package contacts 390 on package pads on the bottom package surface. The package contacts, for example, may be solder balls. In one embodiment, a ball mount process is employed to form the package contacts. Other types of package contacts or processes of forming package contacts may also be useful.

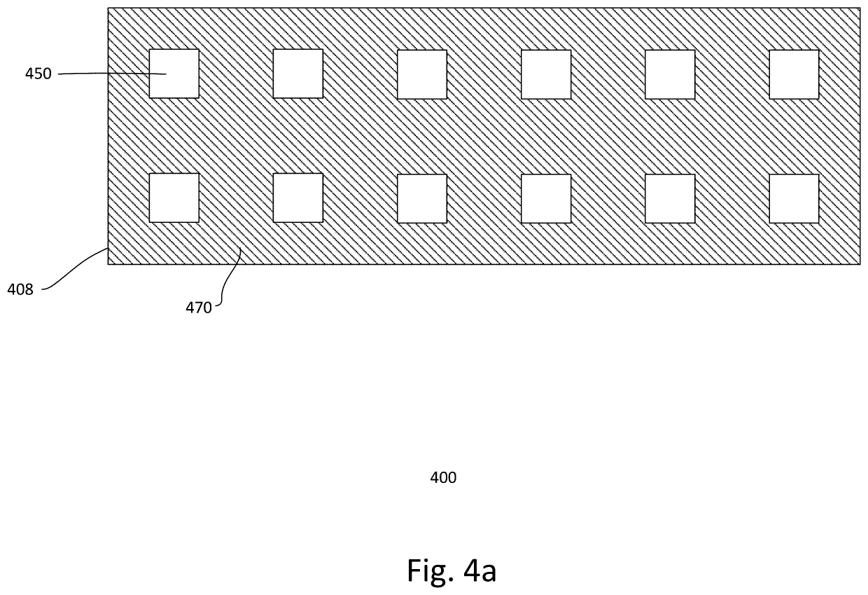

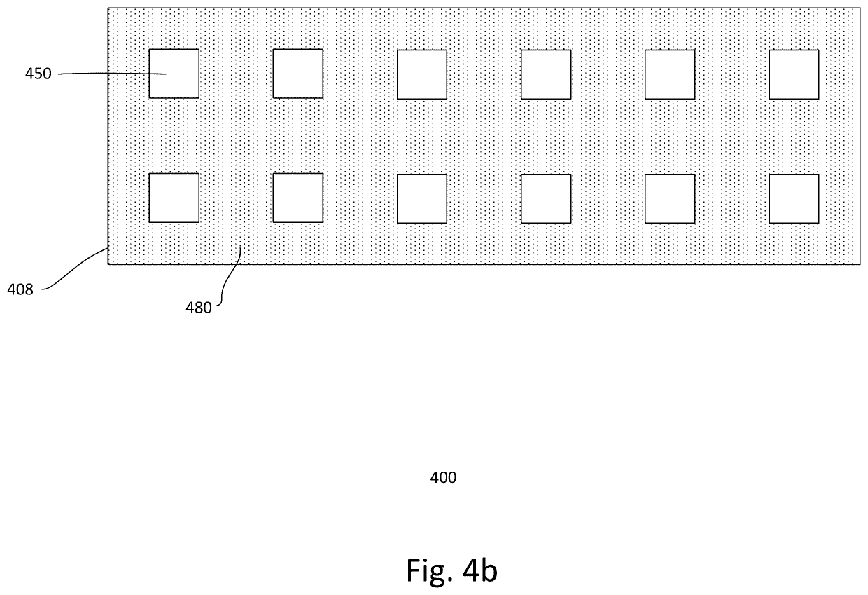

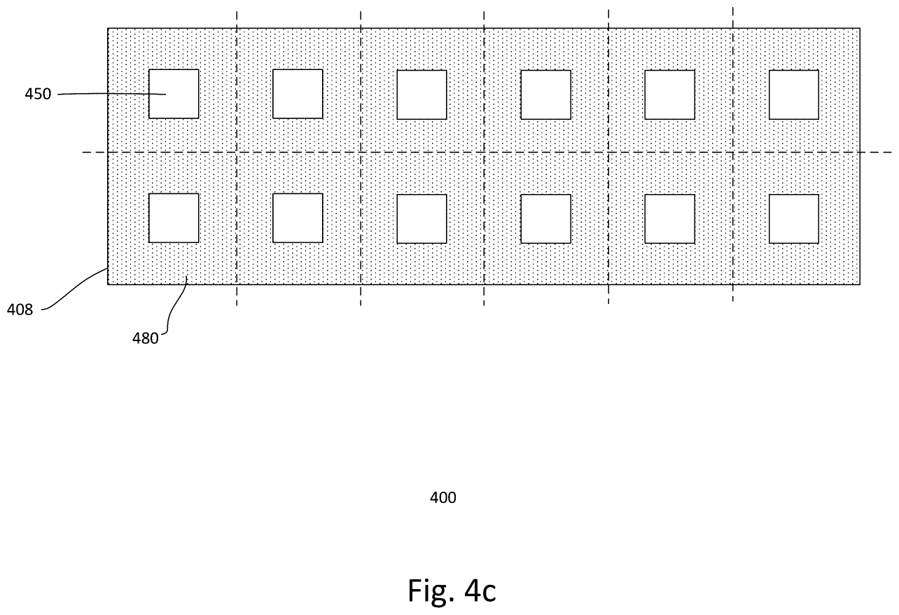

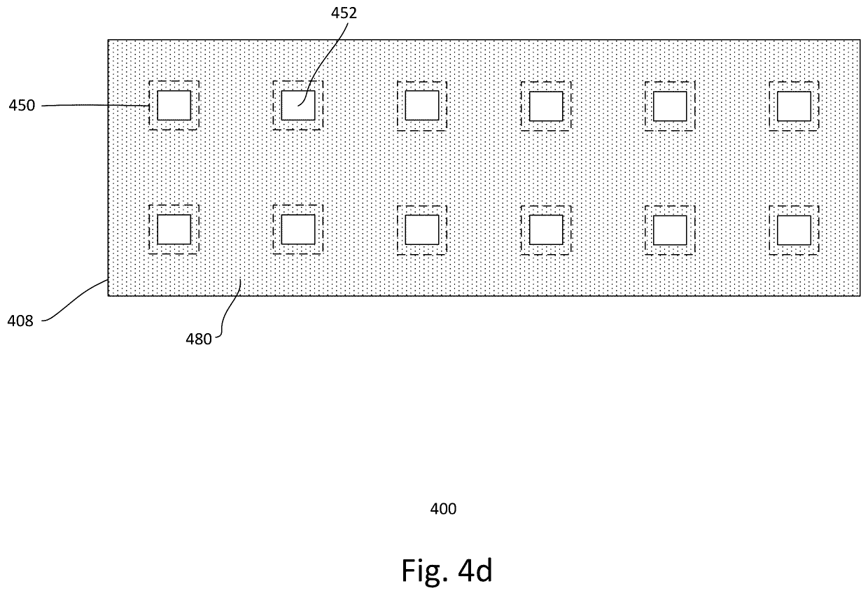

FIGS. 4a-4c show simplified top views of an embodiment of a process flow 400 for forming semiconductor packages in parallel. The semiconductor packages and process flow are similar to those described in FIGS. 1a-1b, 2a-2b and 3a-3f. Common elements may not be described or described in detail.

FIG. 4a shows a multi-package package substrate 408 used for forming multiple semiconductor packages in parallel. The multi-package substrate is configured to form a matrix of 2×6 packages in parallel. Providing a multi-package forming other numbers or matrix configurations of packages may also be useful. As shown, the multi-package substrate is at a stage of processing similar to that described in FIG. 3d. For example, the multi-package package substrate includes an encapsulant 470 encapsulating the packages with covers 450.

Referring to FIG. 4b, an opaque layer 480 is formed on the top surface of the encapsulant of the multi-package package substrate. As shown, the opaque layer leaves the surface of the cover exposed. The opaque layer, in one embodiment, is a black ink layer. The opaque layer is formed on the top surface of the encapsulant by inkjet printing. Other types of opaque layers or deposition techniques may also be useful. The thickness of the opaque layer should be sufficient to prevent the wire bonds encapsulated by the encapsulant from being visible. For example, the thickness of the black ink layer may be about 700 to 725 um. Other thicknesses may also be useful.

As shown in FIG. 4c, the process continues to form package contacts. For example, a ball mount process may be employed to form package contacts. Other types of processes may also be employed to form the package contacts. After forming package contacts, a singulation process is performed to singulate the multi-package package substrate with the packages into individual packages 401. For example, the multi-package substrate is sawed in first and second orthogonal directions, as indicated by the dotted lines. In one embodiment, JIG singulation is employed to singulate the packages of the multi-package package substrate into individual packages. Other singulation techniques, such as laser singulation or a combination of laser and sawing, may also be useful.

FIG. 4d shows an alternative embodiment of forming the opaque layer 480 on the multi-package package substrate. As shown, the opaque layer is configured to cover the top surface of the encapsulant as well as a peripheral portion of the covers. This results in covers 450 with opaque regions 452. For example, the opaque layer is configured to form packages as described in FIGS. 2a-2b. The process continues as described in FIG. 4c to singulate the multi-package package substrate into individual packages.

The inventive concept of the present disclosure may be embodied in other specific forms without departing from the spirit or essential characteristics thereof. The foregoing embodiments, therefore, are to be considered in all respects illustrative rather than limiting the invention described herein. The scope of the invention is thus indicated by the appended claims, rather than by the foregoing description, and all changes that come within the meaning and range of equivalency of the claims are intended to be embraced therein.

What is claimed is:

1. A semiconductor package comprising:
a package substrate with top and bottom major package substrate surfaces, wherein
the top package substrate surface includes a die region with a die pad and a non-die region, the non-die region includes package bond pads and a cover adhesive region surrounding the die region, and
the bottom package substrate surface includes package contact pads, wherein the package contact pads on the bottom package substrate surface are electrically connected to respective package bond pads on the top package substrate surface;
a sensor die having active and non-active major die surfaces, wherein
the active die surface includes a sensor region with a sensor, a non-sensor region with die bond pads and a cover adhesive region surrounding the sensor region, and
the inactive die surface is attached to the die pad;
wire bonds connecting the die bond pads on the active die surface and package bond pads on the top package substrate surface;
a transparent cover disposed over the die covering the sensor region, wherein the cover is attached by a cover adhesive on the cover adhesive region of the active die surface, wherein the cover forms a sealed cavity between the cover and sensor;
a package encapsulation, the package encapsulation encapsulates the package substrate, wire bonds and side cover surfaces and outer sides of the cover adhesive; and
an opaque layer disposed on a top surface of the package encapsulation, wherein the opaque layer obscures the wire bonds within the encapsulation to reduce reflectance to improve sensor performance.

2. The semiconductor package of claim 1 wherein the opaque layer prevents reflectance.

3. The semiconductor package of claim 1 wherein the opaque layer extends beyond the encapsulation and covers a peripheral portion of the cover to form a cover opaque region, wherein the cover opaque region enables the sensor to sense while reducing flaring and scattering to enhance sensor performance.

4. The semiconductor package of claim 3 wherein the opaque layer prevents reflectance.

5. The semiconductor package of claim 3 wherein the opaque layer in the opaque region on the cover prevents flaring and scattering to further enhance sensor performance.

6. The semiconductor package of claim 1 wherein the opaque layer comprises black ink.

7. The semiconductor package of claim 1 wherein the encapsulation comprises an epoxy mold compound.

8. The semiconductor package of claim 1 wherein the sensor die comprises an image sensor die.

9. The semiconductor package of claim 1 wherein the transparent cover comprises a glass cover.

10. The semiconductor package of claim 1 wherein the die bond pads are disposed within the cover adhesive region of the active die surface.

11. A method for forming a semiconductor package comprising:
providing a package substrate with top and bottom major package substrate surfaces, wherein
the top package substrate surface includes a die region with a die pad and a non-die region, the non-die region includes package bond pads and a cover adhesive region surrounding the die region, and
the bottom package substrate surface includes package contact pads, wherein the package contact pads on the bottom package substrate surface are electrically connected to respective package bond pads on the top package substrate surface;
providing a sensor die having active and non-active major die surfaces, wherein
the active die surface includes a sensor region with a sensor, a non-sensor region with die bond pads and a cover adhesive region surrounding the sensor region, and
attaching the inactive die surface of the die to the die pad;
performing wire bonding to electrically connect the die bond pads on the active die surface and package bond pads on the top package substrate surface;
attaching a transparent cover over the die covering the sensor region by a cover adhesive on the cover adhesive region of the top package substrate surface, wherein the cover forms a sealed cavity between the cover and sensor;
encapsulating the package with a package encapsulation, the package encapsulation encapsulates the package substrate, wire bonds and side cover surfaces and outer sides of the cover adhesive; and
forming an opaque layer on a top surface of the package encapsulation, wherein the opaque layer obscures the wire bonds within the encapsulation to reduce reflectance to improve sensor performance.

12. The method of claim 11 wherein the opaque layer prevents reflectance.

13. The method of claim 11 wherein forming the opaque layer comprises forming a black ink layer.

14. The method of claim 13 wherein forming the black ink layer comprises an ink jet process.

15. The method of claim 11 wherein forming the opaque layer comprises forming opaque layer which extends beyond the encapsulation and covers a peripheral portion of the cover to form a cover opaque region, wherein the cover opaque region enables the sensor to sense while reducing flaring and scattering to enhance sensor performance.

16. The method of claim 15 wherein forming the opaque layer comprises forming a black ink layer.

18. The method of claim 14 wherein forming the opaque layer prevents reflectance.

19. A semiconductor package comprising:
a package substrate with top and bottom major package substrate surfaces, wherein
the top package substrate surface includes a die region with a die pad and a non-die region, the non-die region includes package bond pads and a cover adhesive region surrounding the die region, and
the bottom package substrate surface includes package contact pads, wherein the package contact pads on the bottom package substrate surface are electrically connected to respective package bond pads on the top package substrate surface;
a sensor die having active and non-active major die surfaces, wherein
the active die surface includes a sensor region with a sensor, a non-sensor region with die bond pads and a cover adhesive region surrounding the sensor region, and
the inactive die surface is attached to the die pad:
wire bonds connecting the die bond pads on the active die surface and package bond pads on the top package substrate surface;
a transparent cover disposed over the die covering the sensor region, wherein the cover is attached by a cover adhesive on the cover adhesive region of the top package substrate surface, wherein the cover forms a sealed cavity between the cover and sensor;
a package encapsulation, the package encapsulation encapsulates the package substrate, wire bonds and side cover surfaces and outer sides of the cover adhesive; and
an opaque layer disposed on a top surface of the package encapsulation, wherein the opaque layer obscures the wire bonds within the encapsulation to reduce reflectance to improve sensor performance.

20. The device of claim 19 wherein the opaque layer comprises a black ink layer.
